(19) United States
(12) Patent Application Publication
(10) Pub. No.: US 2025/0271774 A1
(43) Pub. Date: Aug. 28, 2025

(54) METHOD OF MANUFACTURING SEMICONDUCTOR DEVICE AND SEMICONDUCTOR DEVICE MANUFACTURING SYSTEM

(71) Applicant: NANYA TECHNOLOGY CORPORATION, New Taipei city (TW)

(72) Inventor: Jung Tzu PENG, New Taipei City (TW)

(21) Appl. No.: 18/588,670

(22) Filed: Feb. 27, 2024

(51) Int. Cl. G03F 7/00; G03F 7/30

(52) U.S. Cl. CPC G03F 7/70533; G03F 7/3028; G03F 7/70508; G03F 7/70525; G03F 7/70725

(57) ABSTRACT

A method of manufacturing a semiconductor device includes supplying a developer on a substrate. A distribution information of the developer on the substrate is captured by a capturing device of an analysis subsystem. An assessment result is generated based on the distribution information by a processor of the analysis subsystem. Whether to perform an adjustment operation is determined based on the assessment result.

### BACKGROUND

### Technical Field

The present disclosure relates to a method of manufacturing a semiconductor device and a semiconductor device manufacturing system.

### Description of Related Art

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling-down has also increased the complexity of processing and manufacturing ICs.

A method of manufacturing a semiconductor device includes forming a resist layer on a substrate, a baking process, a developing process and other operations for creating two-dimensional (2D) and three-dimensional (3D) patterns in microelectronic devices. During the developing process, uneven dispense rate of the developer may cause poor quality of developed resist layer and also adversely affect a quality of the semiconductor device to be manufactured in a subsequent process.

In this regard, how to provide a method of manufacturing a semiconductor device and a semiconductor device manufacturing system that can overcome the aforementioned problem is one of the targets in the research and development in the related fields.

### SUMMARY

One aspect of the present disclosure is a method of manufacturing a semiconductor device.

According to some embodiments of the present disclosure, a method of manufacturing a semiconductor device includes supplying a developer on a substrate. A distribution information of the developer on the substrate is captured by a capturing device of an analysis subsystem. An assessment result is generated based on the distribution information by a processor of the analysis subsystem. Whether to perform an adjustment operation is determined based on the assessment result.

In some embodiments, performing the adjustment operation includes changing a rotational speed of a motor, and the motor is connected to a substrate support stage below the substrate.

In some embodiments, performing the adjustment operation includes changing a thrust of a pump.

In some embodiments, the thrust of the pump is changed such that a dispense rate of the developer is changed.

In some embodiments, if it is determined not to perform the adjustment operation based on the assessment result, a rotational speed of a motor and a thrust of a pump are maintained, and in which the motor is connected to a substrate support stage below the substrate.

In some embodiments, the assessment result is generated by comparing the distribution information with a reference distribution information saved in the analysis subsystem.

In some embodiments, the method further includes transmitting a control signal based on the assessment result from the processor of the analysis subsystem.

In some embodiments, the method further includes rotating the substrate prior to capturing the distribution information of the developer on the substrate.

In some embodiments, the method further includes stopping supplying the developer after determining whether to perform the adjustment operation based on the assessment result.

In some embodiments, the distribution information of the developer on the substrate includes a surface image of the developer on the substrate.

In some embodiments, the method further includes prior to supplying the developer on the substrate, forming a resist layer over the substrate.

Another aspect of the present disclosure is a semiconductor device manufacturing system.

According to some embodiments of the present disclosure, a semiconductor device manufacturing system includes a chamber, a substrate support stage, a nozzle, and an analysis subsystem. The substrate support stage is positioned in the chamber and is configured to support a substrate. The nozzle is positioned over the substrate support stage and is configured to supply a developer on the substrate during a developing process. The analysis subsystem includes a capturing device and a processor. The capturing device of the analysis subsystem is configured to capture a distribution information of the developer on the substrate. The processor of the analysis subsystem is configured to generate an assessment result based on the distribution information, and the processor of the analysis subsystem is further configured to determine whether to perform an adjustment operation based on the assessment result.

In some embodiments, the semiconductor device manufacturing system further includes an adjustment controller connected to the analysis subsystem. The processor of the analysis subsystem is further configured to generate a first control signal and transmit the first control signal to the adjustment controller if it is determined to perform the adjustment operation.

In some embodiments, the adjustment controller is configured to change a rotational speed of a motor in response to the first control signal, and the motor is connected to the substrate support stage and configured to rotate the substrate.

In some embodiments, the adjustment controller is configured to change a thrust of a pump in response to the first control signal, and the pump is connected to the nozzle and configured to adjust a dispense rate of the developer from the nozzle.

In some embodiments, the semiconductor device manufacturing system further includes an adjustment controller connected to the analysis subsystem. The processor of the analysis subsystem is further configured to generate a second control signal and transmit the second control signal to the adjustment controller if it is determined not to perform the adjustment operation.

In some embodiments, the adjustment controller is configured to maintain a rotational speed of a motor and a thrust of a pump in response to the second control signal, the motor is connected to the substrate support stage and configured to rotate the substrate, and the pump is connected to the nozzle and configured to adjust a dispense rate of the developer from the nozzle.

In some embodiments, the processor of the analysis subsystem is configured to generate the assessment result by comparing the distribution information with a reference distribution information.

In some embodiments, the semiconductor device manufacturing system includes an adjustment controller and a main server. The adjustment controller is connected to the analysis subsystem. The connected main server is connected to the adjustment controller, and the main server is configured to start the developing process.

In some embodiments, the capturing device of the analysis subsystem includes at least one camera, and the distribution information of the developer on the substrate includes a surface image of the developer on the substrate.

In the aforementioned embodiments, since the analysis subsystem of the semiconductor device manufacturing system is configured to capture the distribution information of the developer and to generate the assessment result based the distribution information, the developer can be distributed more uniformly (or evenly) over the substrate. As such, a better developing process can be achieved and a quality of the semiconductor device can be improved.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of manufacturing a semiconductor device in accordance with some embodiments of the present disclosure.

FIG. 2 is a schematic view of a semiconductor device manufacturing system in accordance with some embodiments of the present disclosure.

FIG. 3 is a flow chart of a method of manufacturing a semiconductor device in accordance with some embodiments of the present disclosure.

FIGS. 4-6 are schematic views of the semiconductor device, in portion or entirety, at various fabrication stages in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

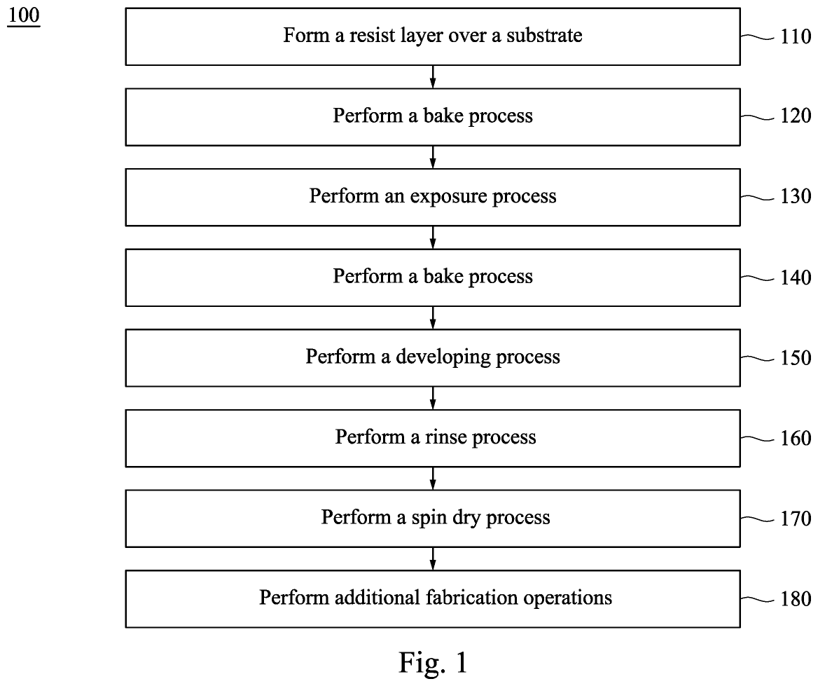

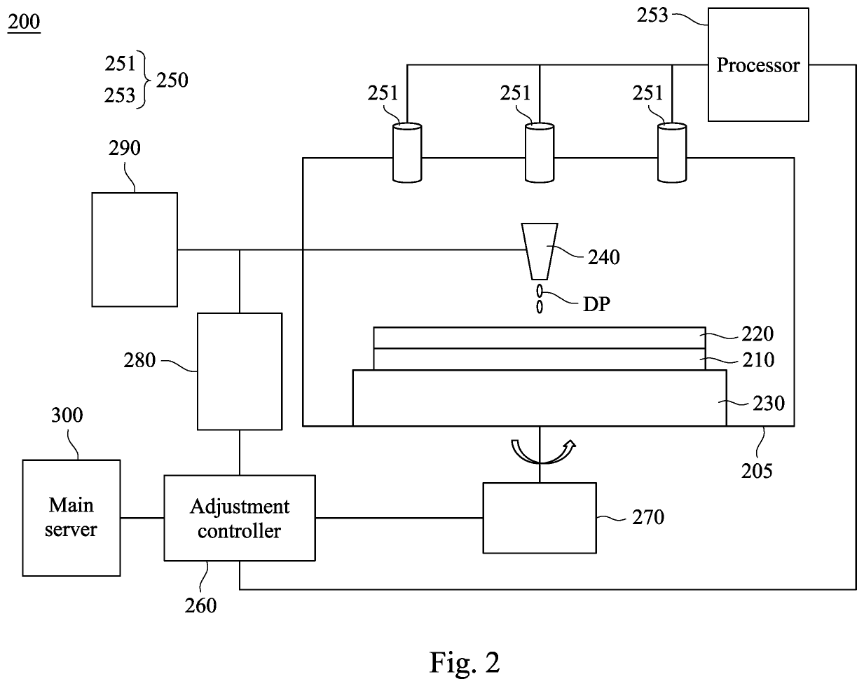

FIG. 1 is a flow chart of a method 100 of manufacturing a semiconductor device (e.g., including a substrate and a resist layer thereon) in accordance with some embodiments of the present disclosure. In some embodiments, the method 100 is implemented, in whole or in part, by a system employing lithography processes, such as deep ultraviolet (DUV) lithography, extreme ultraviolet (EUV) lithography, e-beam lithography, x-ray lithography, and/or other lithography to enhance lithography resolution. For illustration, the method 100 will be described along with the drawings shown in FIGS. 2-7. The method 100 is merely an example, and is not intended to limit the present disclosure beyond what is explicitly recited in the claims. Additional steps (or operations) can be provided before, during, and after the method 100, and some steps described can be replaced, eliminated, or moved around for additional embodiments of the process. For clarity and ease of explanation, some elements of the figures have been simplified.

At step 110, a resist layer is formed over a substrate. In some embodiments, the resist layer is a positive tone resist. In some other embodiments, the resist layer is a negative tone resist.

The substrate (e.g., substrate 210 in FIG. 2) may be a semiconductor substrate (e.g., a wafer), a mask (also called a photomask or reticle), or any base material on which processing may be conducted to provide layers of material to form various features of an IC device. Depending on an IC fabrication stage, the substrate includes various material layers (e.g., dielectric layers, semiconductor layers, and/or conductive layers) configured to form IC features (e.g., doped regions/features, isolation features, gate features, source/drain features (including epitaxial source/drain features), interconnect features, other features, or combinations thereof). In some embodiments, the substrate includes a semiconductor substrate, such as a silicon substrate. The substrate may include another elementary semiconductor, such as germanium; a compound semiconductor, such as silicon carbide, gallium arsenide, gallium phosphide, indium phosphide, indium arsenide, and/or indium antimonide; an alloy semiconductor, such as SiGe, GaAsP, AlInAs, AlGaAs, GaInAs, GaInP, and/or GaInAsP; or combinations thereof.

A resist layer (e.g., resist layer 220 in FIG. 2) is formed over the substrate by a suitable process. For example, the resist layer is formed over the substrate by dropping a photoresist material through a nozzle. The resist layer is also called a photoresist layer, photosensitive layer, imaging layer, patterning layer, or radiation sensitive layer. The resist layer is sensitive to radiation used during a lithography exposure process, such as DUV radiation, EUV radiation, e-beam radiation, ion beam radiation, and/or other suitable radiation.

In some embodiments, the resist layer includes a positive tone resist. When a developer is a positive tone developer (PTD), portions of the positive tone resist exposed to radiation become soluble to the developer, and unexposed portions of the positive tone resist remain insoluble to the developer. When a developer is a negative tone developer (NTD), portions of the positive tone resist exposed to radiation become insoluble to the developer, and unexposed portions of the positive tone resist remain soluble (or exhibit increased solubility) to the developer. For example, when the negative tone developer such as a hydrophobic organic solvent applied to the exposed portions of the positive tone resist, the unexposed (hydrophobic) portions of the positive tone resist are dissolved by the NTD and the exposed (hydrophilic) portions of the positive tone resist remain after the developing process to form a developed resist layer.

In some other embodiments, the resist layer includes a negative tone resist. When a developer is the positive tone developer, portions of the resist layer exposed to radiation become insoluble (or exhibit decreased solubility) to the developer, and unexposed portions of the negative tone resist remain soluble to the developer. When a developer is a negative tone developer (NTD), portions of the negative tone resist exposed to radiation become soluble to the developer, and unexposed portions of the negative tone resist remain insoluble to the developer.

At step 120 of FIG. 1, a bake process is performed. In some embodiments, the resist layer is baked at an elevated temperature using a pre-exposure baking process to evaporate solvents in the resist layer. In some embodiments, the baking process is performed at a temperature suitable to evaporate the solvent, and the temperature depends upon the materials chosen for the resist layer. The baking process is performed for a time sufficient to cure and dry the resist layer.

At step 130 of FIG. 1, an exposure process is performed. In some embodiments, the resist layer is exposed to radiation in the form of electromagnetic waves. In some embodiments, the radiation includes DUV radiation, EUV radiation, x-ray radiation, e-beam radiation, ion-beam radiation, and/or other suitable radiation. The exposure process can be in air or liquid, or vacuum. In some embodiments, the radiation is patterned using a mask having an IC pattern defined therein, such that the patterned radiation forms an image of the IC pattern on the resist layer. The mask transmits, absorbs, and/or reflects the radiation depending on the IC pattern, along with mask technologies used to fabricate the mask. In some embodiments, the radiation beam is patterned by directly modulating the radiation beam according to an IC pattern without using a mask (sometimes called maskless lithography).

At step 140 of FIG. 1, a bake process is performed. In some embodiments, the exposed resist layer is baked at an elevated temperature using a post-exposure baking process. Specifically, after the exposure process, a post-exposure baking process may be performed on the resist layer.

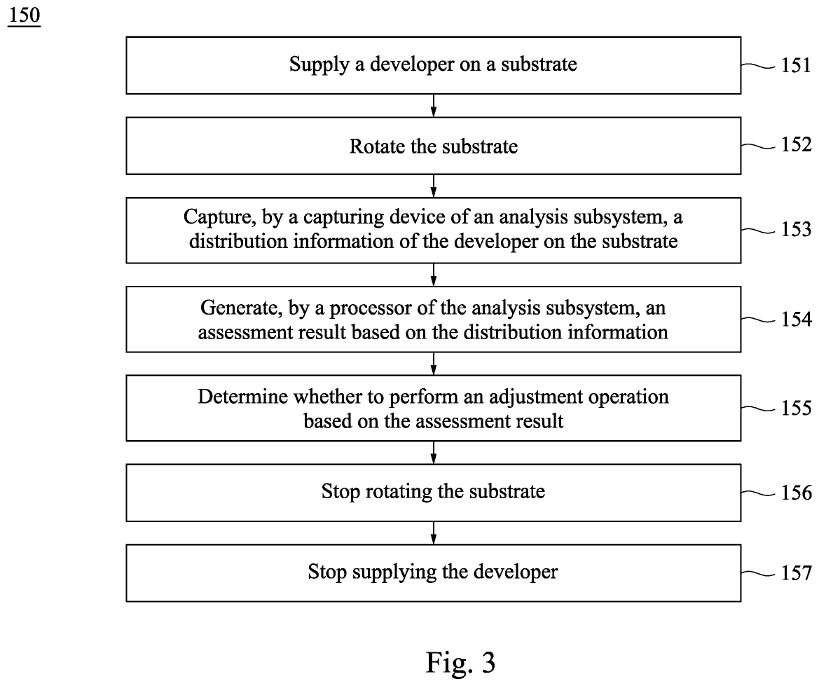

At step 150 of FIG. 1, a developing process is performed. FIG. 2 is a schematic view of a semiconductor device manufacturing system 200 in accordance with some embodiments of the present disclosure, and FIG. 3 is a flow chart of the step 150 of the method 100 in FIG. 1 in accordance with some embodiments of the present disclosure. The step 150 may include multiple steps/operations 151-157 (see FIG. 3) and can be performed by using the semiconductor device manufacturing system 200 shown in FIG. 2. For illustration, the flow chart of the step 150 will be described along with the drawings shown in FIGS. 2 and 3. The flow chart shown in FIG. 3 is merely an example, and is not intended to limit the present disclosure beyond what is explicitly recited in the claims. Additional operations can be provided before, during, and after the step 150, and some steps described can be replaced, eliminated, or moved around for additional embodiments of the process. For clarity and ease of explanation, some elements of the figures have been simplified.

Reference is made to FIG. 2. The semiconductor device manufacturing system 200 includes a chamber 205, a substrate support stage 230, a nozzle 240, and an analysis subsystem 250. The substrate support stage 230 is positioned in the chamber 205 and configured to support a substrate 210 (e.g., silicon wafer) and a resist layer 220 on the substrate 210. The nozzle 240 is positioned in the chamber 205 and over the substrate support stage 230, and the nozzle 240 is configured to supply a developer DP on the substrate 210 (or the resist layer 220 on the substrate 210) during a developing process. The analysis subsystem 250 includes a capturing device 251 and a processor 253. The capturing device 251 of the analysis subsystem 250 is configured to capture a distribution information of the developer DP on the substrate 210 (or the resist layer 220). The processor 253 of the analysis subsystem 250 is configured to generate an assessment result based on the distribution information, and the processor 253 of the analysis subsystem 250 is further configured to determine whether to perform an adjustment operation based on the assessment result. With such configuration, the developer DP can be distributed more uniformly (or evenly) over the substrate 210 (or on the resist layer 220). As such, the better developing process can be achieved and a quality of the semiconductor device can be improved.

In some embodiments, the semiconductor device manufacturing system 200 further includes an adjustment controller 260, a motor 270, a pump 280, and a developer source 290. The adjustment controller 260 is connected to the analysis subsystem 250, the motor 270, and the pump 280. The motor 270 is connected to the substrate support stage 230 and the adjustment controller 260, and the motor 270 is configured to rotate the substrate support stage 230 and also the layers (i.e., the substrate 210 and the resist layer 220) on the substrate support stage 230. The pump 280 is connected to the nozzle 240, the adjustment controller 260, and the developer source 290, and the pump 280 is configured to adjust a dispense rate of the developer DP from the nozzle 240. The developer source 290 is connected to the nozzle 240 in the chamber 205 through a gas line, and the developer source 290 is configured to provide the developer DP.

In some embodiments, the adjustment controller 260 is configured to adjust/change a rotational speed of the motor 270 such that a distribution of the developer DP on the substrate 210 is changed. For example, by increasing the rotational speed of the motor 270, the developer DP flowing from the nozzle 240 spreads over the entire substrate 210 faster; and by decreasing the rotational speed of the motor 270, the developer DP flowing from the nozzle 240 spreads over the entire substrate 210 slower. The adjustment controller 260 is further configured to adjust/change a thrust of the pump 280 such that a distribution of the developer DP on the substrate 210 is changed. For example, by increasing the thrust of the pump 280, a dispense rate (or a flow) of the developer DP flowing from the nozzle 240 is increased such that the developer DP spreads over the entire substrate 210 faster; and by decreasing the thrust of the pump 280, the dispense rate (or the flow) of the developer DP flowing from the nozzle 240 is decreased such that the developer DP spreads over the entire substrate 210 slower. As a result, by adjusting the rotational speed of the motor 270 and/or the thrust of the pump 280 through the adjustment controller 260, the developer DP can be distributed more uniformly over the substrate 210.

In some embodiments, the processor 253 of the analysis subsystem 250 is further configured to generate a first control signal and transmit the first control signal to the adjustment controller 260 if it is determined to perform the adjustment operation. The adjustment controller 260 then changes the rotational speed of the motor 270 and/or the thrust of the pump 280 in response to the first control signal. In some embodiments, the processor 253 of the analysis subsystem 250 is a central processing unit (CPU), a controller, or other analytical devices with analysis capabilities.

In some embodiments, the processor 253 of the analysis subsystem 250 is further configured to generate a second control signal and transmit the second control signal to the adjustment controller 260 if it is determined to not perform the adjustment operation. The adjustment controller 260 then maintain (i.e., does not change) the rotational speed of the motor 270 and/or the thrust of the pump 280 in response to the second control signal.

In some embodiments, the processor 253 of the analysis subsystem 250 is configured to generate the assessment result by comparing the distribution information with a reference distribution information. The reference distribution information may be a uniform distribution information of the developer on the substrate analyzed previously. By comparing the distribution information with the reference distribution information, non-uniform (or uneven) distribution of the developer DP can be identified and thus the assessment result is generated.

If the processor 253 of the analysis subsystem 250 determines (or assesses) that the distribution information is not similar to the reference distribution information, then the assessment result indicates that the distribution information of the developer DP is not uniform. As a result, the processor 253 of the analysis subsystem 250 determines to perform the adjustment operation. On the other hand, if the processor 253 of the analysis subsystem 250 determines (or assesses) that the distribution information is similar to the reference distribution information, then the assessment result indicates that the distribution information of the developer DP is uniform. As a result, the processor 253 of the analysis subsystem 250 determines not to perform the adjustment operation. In some embodiments, the reference distribution information is saved in a storage unit (e.g., DRAM, a mechanical disk, a solid-state drive, or other types of storage medium as deemed appropriate) of the analysis subsystem 250.

In some embodiments, the capturing device 251 of the analysis subsystem 250 includes at least one camera (e.g., one to ten cameras). The capturing device 251 may have high-speed camera lenses (e.g., greater than 10000 frame per second). The capturing device 251 of the analysis subsystem 250 is configured to capture multiples images (e.g., 3 to 10 images) in one second. In some embodiments, the distribution information of the developer DP on the substrate 210 includes a surface image of the developer DP on the substrate 210.

In some embodiments, the processor 253 of the analysis subsystem 250 is configured to generate the assessment result using AI-based image recognition scheme. In some embodiments, the processor 253 of the analysis subsystem 250 is configured to use the distribution information (e.g., surface image) captured by the capturing device 251 as an input to a function generated by running a machine learning algorithm on a training data set. The training data set may include multiple training examples. Each of the training example may include: (a) a distribution information of a developer on a substrate or at least one feature (e.g., location of the developer with respect to the substrate, time, relationship between the location of the developer and the time, etc.) derived from the distribution information; and (b) the classification of the distribution information or the features (e.g., whether the distribution information or the features indicate that the developer DP in the distribution information is uniform distribution or not uniform distribution). When the distribution information captured by the capturing device 251 of the analysis subsystem 250 is received as the input, the function provides an output of whether the developer DP in the distribution information is uniform distribution or not uniform distribution (i.e., the assessment result). The processor 253 of the analysis subsystem 250 can generate the assessment result regarding the uniform/non-uniform distribution of the developer DP based on the output of the function.

In some embodiments, the function is generated on an external computing hardware, and the processor 253 of the analysis subsystem 250 receives the function from said external computing hardware. In other embodiments, the distribution information captured by the capturing device 251 of the analysis subsystem 250 is transmitted to the external computing hardware. The external computing hardware applies the function to the distribution information captured by the capturing device 251 of the analysis subsystem 250 and transmits the output of the function to the processor 253 of the analysis subsystem 250.

In some embodiments, the semiconductor device manufacturing system 200 includes a main server 300 connected to the adjustment controller 260. The main server 300 is configured to start the developing process. In some embodiments, the main server 300 determines a sequence and timing of the developing process (i.e., the step 150). For example, the main server 300 determines when to supply the developer DP, when to rotate the substrate 210, when to stop rotating the substrate 210, and when to stop supplying the developer DP. In some embodiments, with the collaborative work of the analysis subsystem 250, the adjustment controller 260, and the main server 300, the uniformity of developer coating can be dynamically controlled in real time and the abnormal coating can be detected continuously.

Referring to FIG. 3, at step 151, a developer on a substrate is supplied. Referring to FIGS. 2 and 3, in some embodiments of the step 151, the developer DP is supplied from the nozzle 240 on the substrate 210 (or on the resist layer 220). In some embodiments, the main server 300 determines when to supply the developer DP. In some embodiments, the adjustment controller 260 applies the thrust on the pump 280 during supplying the developer DP.

At step 152, the substrate is rotated. Referring to FIGS. 2 and 3, in some embodiments of the step 152, the substrate 210 is rotated by the motor 270. For example, in FIGS. 2 and 3, the adjustment controller 260 controls the motor 270, the motor 270 drives the substrate support stage 230 to rotate, and the substrate 210 and the resist layer 220 are rotated accordingly to spread the developer DP. In some embodiments, the main server 300 determines when to rotate the substrate 210. In some embodiments, the substrate 210 is rotated after supplying the developer DP on the substrate 210.

At step 153, a distribution information of the developer on the substrate is captured by a capturing device of an analysis subsystem. Referring to FIGS. 2 and 3, in some embodiments of the step 153, the distribution information of the developer DP on the substrate 210 is captured by the capturing device 251 of the analysis subsystem 250. In some embodiments, the substrate 210 is rotated prior to capturing the distribution information of the developer DP on the substrate 210.

At step 154, an assessment result is generated, by a processor of the analysis subsystem, based on the distribution information. Referring to FIGS. 2 and 3, in some embodiments of the step 154, the assessment result is generated, by the processor 253 of the analysis subsystem 250, based on the distribution information. In some embodiments, the assessment result is generated based on the distribution information by comparing the distribution information with the reference distribution information saved in the storage unit of the analysis subsystem 250. In some embodiments, the distribution information of the step 153 and the assessment result of the step 154 are saved in the storage unit of the analysis subsystem 250 for training the analysis subsystem 250.

At step 155, whether to perform an adjustment operation based on the assessment result is determined. Referring to FIGS. 2 and 3, in some embodiments of the step 155, whether to perform an adjustment operation based on the assessment result is determined by the processor 253 of the analysis subsystem 250. In some embodiments, the step 150 further includes transmitting the first control signal or the second control signal based on the assessment result from the processor 253 of the analysis subsystem 250 to the adjustment controller 260. In some embodiments, the first control signal indicates to perform the adjustment operation, while the second control signal indicates not to perform the adjustment operation. In greater details, if it is determined to perform the adjustment operation based on the assessment result, the processor 253 of the analysis subsystem 250 demands (e.g., by transmitting the first control signal) the adjustment controller 260 to perform the adjustment operation. The adjustment operation may be performed by changing the rotational speed of the motor 270 and/or changing the thrust of the pump 280. For example, a first rotational speed of the motor 270 in step 152 is different from a second rotational speed of the motor 270 after step 155 (e.g., performing the adjustment operation). The dispense rate of the developer DP is thus changed by changing the rotational speed of the motor 270 and/or changing the thrust of the pump 280. On the other hand, if it is determined not to perform the adjustment operation based on the assessment result, the processor 253 of the analysis subsystem 250 demands (e.g., by transmitting the second control signal) the adjustment controller 260 not to perform the adjustment operation. In other words, the rotational speed of the motor 270 and the thrust of the pump 280 are maintained (i.e., not changed). The dispense rate of the developer DP is maintained (i.e., not changed) accordingly. In some embodiments, the step 150 further includes transmitting a warring message corresponding to the first control signal from the processor 253 of the analysis subsystem 250 to the operators.

At step 156, rotating the substrate is stopped. Referring to FIGS. 2 and 3, in some embodiments of the step 156, rotating the substrate 210 is stopped by the motor 270. For example, in FIGS. 2 and 3, the adjustment controller 260 controls the motor 270, the rotational speed of the motor 270 is decreased to zero, and thus rotating the substrate 210 is stopped accordingly. In some embodiments, the main server 300 determines when to stop rotating the substrate 210.

At step 157, supplying the developer is stopped. Referring to FIGS. 2 and 3, in some embodiments of the step 157, supplying the developer DP from the nozzle 240 is stopped. In some embodiments, the main server 300 determines when to stop supplying the developer DP. In some embodiments, after stopping rotating the substrate 210, supplying the developer DP is stopped. In some other embodiments, rotating the substrate 210 is stopped after stopping supplying the developer DP. In some embodiments, supplying the developer DP is stopped after determining whether to perform the adjustment operation based on the assessment result. In some embodiments, since capturing the distribution information of the developer DP, generating the assessment result, and determining whether to perform the adjustment operation are performed prior to stopping supplying the developer, the uniformity of developer coating can be dynamically controlled in real time and the abnormal coating can be avoided. As such, the developer DP can be more uniformly distributed (or coated) over the resist layer 220. In some embodiments, capturing the distribution information of the developer DP, generating the assessment result, and determining whether to perform the adjustment operation are performed during supplying the developer DP. In other words, the developer DP is supplied from the nozzle 240 continuously when performing the steps 152-156 (particularly the steps 153-155).

In some embodiments, as shown in FIGS. 1-4, the developing process of the step 150 is performed to remove portions of the resist layer 220. The developer DP is applied to the resist layer 220 and dissolves the portion of the resist layer 220, leaving the developed resist layer 220 having opening(s) 225 defined therein.

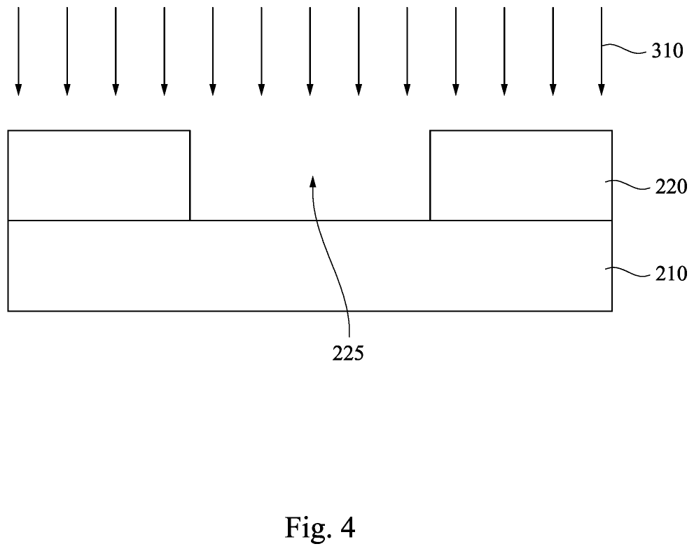

Referring back to FIG. 1, the method 100 then proceeds to step 160 after the step 150, where a rinse process is performed. Referring to FIGS. 1 and 4, in some embodiments of the step 160, the rinse process is performed on the developed resist layer 220 using a basic aqueous rinse solution. In some embodiments, the rinse process is performed after the developing process, for example, to remove any residue and/or particles from the semiconductor device. In some embodiments, a rinse solution 310 is applied to the developed resist layer 220 to remove unwanted materials. The rinse solutions 310 may use organic solvent.

At step 170 in FIG. 1, a spin dry process is performed. Referring to FIGS. 1 and 4, in some embodiments of the step 170, spin dry process is performed on the developed (or referred as patterned) resist layer 220 to further remove any liquids and/or solids remaining on the patterned resist layer 220 after the rinsing process. The rinsing solution 310 may be substantially removed by the spin dry process. During the spin dry process, the rinsing solution 310 is spun away from the substrate center towards the substrate edge and then removed.

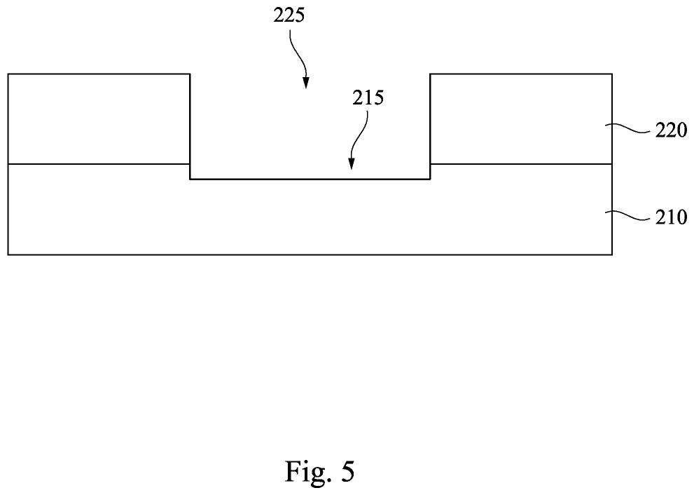

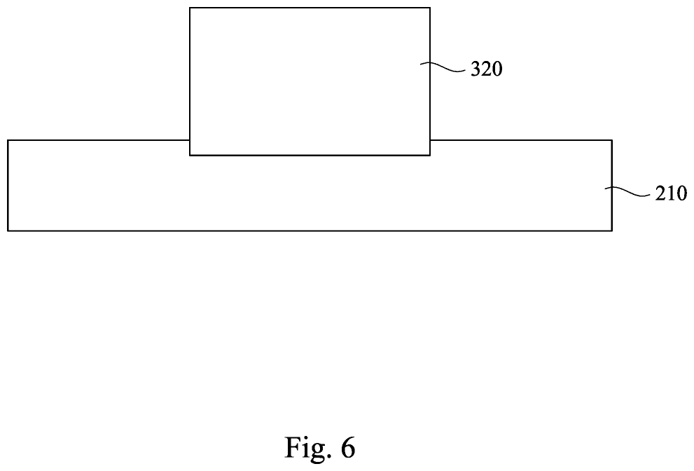

At step 180 in FIG. 1, additional fabrication operations are performed. Referring to FIGS. 1, 5, and 6, in some embodiments of the step 180, additional fabrication operations are performed on the semiconductor device using the patterned resist layer 220 as a mask. For example, the fabrication operation is applied within the opening 225 (see FIG. 5) of the patterned resist layer 220, while other portions of the substrate 210 covered by the patterned resist layer 220 are protected from being impacted by the fabrication operation. In some embodiments, a pattern of the opening 225 in the resist layer 220 is extended into the layer to be patterned or substrate 210 to create a pattern of opening(s) 215 in the substrate 210, thereby transferring the pattern in the resist layer 220 into the substrate 210. The pattern is extended into the substrate 210 by etching, using one or more suitable etchants. The resist layer 220 is at least partially removed during the etching operation in some embodiments. In other embodiments, the resist layer 220 is removed after etching the substrate 210 by using a suitable photoresist stripper solvent or by a photoresist ashing operation. In some embodiments, a deposition process is performed to fill the opening 215 of the substrate 210 with a conductive material, thereby forming conductive lines 320 over the substrate 210 as shown in FIG. 6.

In summary, the analysis subsystem of the semiconductor device manufacturing system captures the distribution information of the developer and generates the assessment result based the distribution information, the developer can be distributed more uniformly (or evenly) over the substrate. As such, the better developing process can be achieved and a quality of the semiconductor device can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor device, comprising:
supplying a developer on a substrate;
capturing, by a capturing device of an analysis subsystem, a distribution information of the developer on the substrate;
generating, by a processor of the analysis subsystem, an assessment result based on the distribution information; and
determining whether to perform an adjustment operation based on the assessment result.

2. The method of claim 1, wherein performing the adjustment operation comprises changing a rotational speed of a motor, and wherein the motor is connected to a substrate support stage below the substrate.

3. The method of claim 1, wherein performing the adjustment operation comprises changing a thrust of a pump.

4. The method of claim 3, wherein the thrust of the pump is changed such that a dispense rate of the developer is changed.

5. The method of claim 1, wherein if it is determined not to perform the adjustment operation based on the assessment result, a rotational speed of a motor and a thrust of a pump are maintained, and wherein the motor is connected to a substrate support stage below the substrate.

6. The method of claim 1, wherein the assessment result is generated by comparing the distribution information with a reference distribution information saved in the analysis subsystem.

7. The method of claim 1, further comprising:
transmitting a control signal based on the assessment result from the processor of the analysis subsystem.

8. The method of claim 1, further comprising:
rotating the substrate prior to capturing the distribution information of the developer on the substrate.

9. The method of claim 1, further comprising:
stopping supplying the developer after determining whether to perform the adjustment operation based on the assessment result.

10. The method of claim 1, wherein the distribution information of the developer on the substrate includes a surface image of the developer on the substrate.

11. The method of claim 1, further comprising:
forming a resist layer over the substrate prior to supplying the developer on the substrate.

12. A semiconductor device manufacturing system, comprising:
a chamber;
a substrate support stage positioned in the chamber and configured to support a substrate;
a nozzle positioned over the substrate support stage and configured to supply a developer on the substrate during a developing process; and
an analysis subsystem comprising:
a capturing device configured to capture a distribution information of the developer on the substrate; and
a processor configured to generate an assessment result based on the distribution information, wherein the processor is further configured to determine whether to perform an adjustment operation based on the assessment result.

13. The semiconductor device manufacturing system of claim 12, further comprising:
an adjustment controller connected to the analysis subsystem, wherein the processor of the analysis subsystem is further configured to generate a first control signal and transmit the first control signal to the adjustment controller if it is determined to perform the adjustment operation.

14. The semiconductor device manufacturing system of claim 13, wherein the adjustment controller is configured to change a rotational speed of a motor in response to the first control signal, and wherein the motor is connected to the substrate support stage and configured to rotate the substrate.

15. The semiconductor device manufacturing system of claim 13, wherein the adjustment controller is configured to change a thrust of a pump in response to the first control signal, and wherein the pump is connected to the nozzle and configured to adjust a dispense rate of the developer from the nozzle.

16. The semiconductor device manufacturing system of claim 12, further comprising:
an adjustment controller connected to the analysis subsystem, wherein the processor of the analysis subsystem is further configured to generate a second control signal and transmit the second control signal to the adjustment controller if it is determined not to perform the adjustment operation.

17. The semiconductor device manufacturing system of claim 16, wherein the adjustment controller is configured to maintain a rotational speed of a motor and a thrust of a pump in response to the second control signal, wherein the motor is connected to the substrate support stage and configured to rotate the substrate, and wherein the pump is connected to the nozzle and configured to adjust a dispense rate of the developer from the nozzle.

18. The semiconductor device manufacturing system of claim 12, wherein the processor of the analysis subsystem is configured to generate the assessment result by comparing the distribution information with a reference distribution information.

19. The semiconductor device manufacturing system of claim 12, further comprising:
an adjustment controller connected to the analysis subsystem, and
a main server connected to the adjustment controller, wherein the main server is configured to start the developing process.

20. The semiconductor device manufacturing system of claim 12, wherein the capturing device of the analysis subsystem includes at least one camera, and wherein the distribution information of the developer on the substrate includes a surface image of the developer on the substrate.
